(19) United States
(12) Patent Application Publication
(10) Pub. No.: US 2024/0155914 A1
(43) Pub. Date: May 9, 2024

(54) DISPLAY APPARATUS

(71) Applicant: Samsung Display Co., Ltd., Yongin-si (KR)

(72) Inventors: Hyuneok Shin, Yongin-si (KR); Joonyong Park, Yongin-si (KR)

(21) Appl. No.: 18/503,952

(22) Filed: Nov. 7, 2023

(30) Foreign Application Priority Data
Nov. 9, 2022 (KR) 10-2022-0148975

(51) Int. Cl. H10K 59/80; H10K 59/122; H10K 59/88

(52) U.S. Cl. CPC H10K 59/80523; H10K 59/122; H10K 59/873; H10K 59/88; H10K 2102/351

(57) ABSTRACT

A display apparatus includes a first subpixel electrode, a metal bank layer having a first opening overlapping the first subpixel electrode, and including a first metal layer and a second metal layer on the first metal layer, a first intermediate layer overlapping the first subpixel electrode through the first opening of the metal bank layer, and a first opposite electrode on the first intermediate layer and positioned in the first opening of the metal bank layer, wherein the first opposite electrode includes an aluminum (Al)-based alloy including aluminum (Al) and at least two elements other than the aluminum (Al).

### CROSS-REFERENCE TO RELATED APPLICATION

This application claims priority to and the benefit of Korean Patent Application No. 10-2022-0148975, filed on Nov. 9, 2022, in the Korean Intellectual Property Office, the disclosure of which is incorporated by reference herein in its entirety.

### BACKGROUND

### 1. Field

Aspects of embodiments of the present disclosure relate to a structure of a display apparatus.

### 2. Description of the Related Art

Display apparatuses may visually display data. Such a display apparatus may include a substrate divided into a display area and a peripheral area. The display area may include a scan line and a data line insulated from each other and may include a plurality of pixels. Also, the display area may include a thin film transistor corresponding to each of the pixels and a subpixel electrode electrically connected to the thin film transistor. Also, the display area may include an opposite electrode commonly provided in the pixels. The peripheral area may include various lines configured to transmit electrical signals to the display area, a scan driver, a data driver, a controller, a pad portion, and the like.

Display apparatuses have been used for various purposes. Accordingly, various designs have been attempted to improve the quality of display apparatuses.

The above information disclosed in this Background section is only for enhancement of understanding of the background of the invention and therefore it may contain information that does not form the prior art.

### SUMMARY

Aspects of some embodiments of the present disclosure are directed to a display apparatus that has an improved resolution and may implement a high-quality image.

Additional aspects will be set forth in part in the description which follows and, in part, will be apparent from the description, or may be learned by practice of the presented embodiments of the disclosure.

According to some embodiments, there is provided a display apparatus including: a first subpixel electrode; a metal bank layer having a first opening overlapping the first subpixel electrode, and including a first metal layer and a second metal layer on the first metal layer; a first intermediate layer overlapping the first subpixel electrode through the first opening of the metal bank layer; and a first opposite electrode on the first intermediate layer and positioned in the first opening of the metal bank layer, wherein the first opposite electrode includes an aluminum (AD-based alloy including aluminum (Al) and at least two elements other than the aluminum (Al).

In some embodiments, a sum of contents of the at least two elements is about 0.05 at % to about 0.1 at %.

In some embodiments, the at least two elements of the first opposite electrode include: at least one of nickel (Ni), palladium (Pd), platinum (Pt), darmstadtium (Ds), and cobalt (Co); and at least one of lanthanum (La), cerium (Ce), praseodymium (Pr), neodymium (Nd), and germanium (Ge).

In some embodiments, the at least two elements of the first opposite electrode include: at least one of a Group 9 metal element and a Group 10 metal element; and at least one of a lanthanum group metal element and germanium (Ge).

In some embodiments, the first opposite electrode includes an aluminum (Al)-based alloy including aluminum (Al), nickel (Ni), and lanthanum (La), a content of the nickel (Ni) is about 0.01 at % to about 0.05 at %, and a content of the lanthanum (La) is about 0.01 at % to about 0.1 at %.

In some embodiments, the content of the lanthanum (La) is equal to or greater than the content of the nickel (Ni).

In some embodiments, the first opposite electrode includes a first layer and a second layer on the first layer, and the second layer includes an aluminum (Al)-based alloy.

In some embodiments, the first layer includes at least one of ytterbium (Yb), scandium (Sc), vanadium (V), yttrium (Y), indium (In), cerium (Ce), samarium (Sm), europium (Eu), and terbium (Tb).

In some embodiments, a thickness of the second layer is about 100 Å to about 200 Å.

In some embodiments, a thickness of the first layer is about 5 Å to about 30 Å.

In some embodiments, a transmittance of the first opposite electrode including the second layer is about 40% to about 60%.

In some embodiments, an outer portion of the first opposite electrode contacts a side surface of the first metal layer facing the first opening.

In some embodiments, a portion of the second metal layer facing the first opening of the metal bank layer includes a tip extending toward the first opening from a point where a bottom surface of the second metal layer and a side surface of the first metal layer contact each other.

In some embodiments, the display apparatus further includes: a first dummy intermediate layer including a same material as the first intermediate layer and on the second metal layer; and a first dummy opposite electrode including a same material as the first opposite electrode and on the first dummy intermediate layer.

In some embodiments, the display apparatus further includes: an insulating layer on the first subpixel electrode and under the metal bank layer; and a protection layer arranged between an outer portion of the first subpixel electrode and the insulating layer, wherein the protection layer includes a transparent conductive oxide (TCO).

According to some embodiments, there is provided a display apparatus including: a first subpixel electrode; a metal bank layer having a first opening overlapping the first subpixel electrode, and including a first metal layer and a second metal layer over the first metal layer; a first intermediate layer overlapping the first subpixel electrode in the first opening of the metal bank layer; a first opposite electrode on the first intermediate layer and positioned in the first opening of the metal bank layer; a first dummy intermediate layer including a same material as the first intermediate layer and on the second metal layer; and a first dummy opposite electrode including a same material as the first opposite electrode and on the first dummy intermediate layer, wherein the first opposite electrode and the first dummy opposite electrode includes an aluminum (Al)-based alloy including aluminum (Al) and at least two elements other than the aluminum (Al).

In some embodiments, a sum of contents of the at least two elements is about 0.05 at % to about 0.1 at %.

In some embodiments, the at least two elements of the first opposite electrode and the first dummy opposite electrode include: at least one of nickel (Ni), palladium (Pd), platinum (Pt), darmstadtium (Ds), and cobalt (Co); and at least one of lanthanum (La), cerium (Ce), praseodymium (Pr), neodymium (Nd), and germanium (Ge).

In some embodiments, the first opposite electrode and the first dummy opposite electrode include a first layer and a second layer on the first layer, the first layer includes at least one of ytterbium (Yb), scandium (Sc), vanadium (V), yttrium (Y), indium (In), cerium (Ce), samarium (Sm), europium (Eu), and terbium (Tb), and wherein the second layer includes the aluminum (Al)-based alloy.

In some embodiments, the display apparatus further includes: a second subpixel electrode; a second intermediate layer overlapping the second subpixel electrode and positioned in a second opening of the metal bank layer; a second opposite electrode overlapping the second intermediate layer and positioned in the second opening of the metal bank layer; a second dummy intermediate layer including a same material as the second intermediate layer and on the second metal layer; and a second dummy opposite electrode including a same material as the second opposite electrode and on the second dummy intermediate layer, wherein the first dummy opposite electrode and the second dummy opposite electrode are offset from each other, and wherein the first opposite electrode, the second opposite electrode, the first dummy opposite electrode, and the second dummy opposite electrode include a same material.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are perspective views schematically illustrating a display apparatus according to some embodiments of the present disclosure;

FIGS. 2A and 2B are equivalent circuit diagrams schematically illustrating a light emitting diode corresponding to a subpixel of a display apparatus and a subpixel circuit electrically connected to the light emitting diode, according to some embodiments of the present disclosure;

FIGS. 3A to 3J are cross-sectional views schematically illustrating states in a manufacturing process of a display apparatus according to some embodiments of the present disclosure;

FIG. 3K is a cross-sectional view illustrating a stacked structure of a light emitting diode according to some embodiments of the present disclosure;

FIG. 4 is a cross-sectional view schematically illustrating a display apparatus according to some embodiments of the present disclosure;

FIG. 5 is a cross-sectional view schematically illustrating an opposite electrode of a display apparatus according to some embodiments of the present disclosure; and

FIG. 6 is a diagram for describing an opposite electrode of a display apparatus according to some embodiments of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein.

Sizes of elements in the drawings may be exaggerated for convenience of description In other words, because the sizes and thicknesses of elements in the drawings are arbitrarily illustrated for convenience of description, the disclosure is not limited thereto.

When a certain embodiment may be implemented differently, a particular process order may be performed differently from the described order. For example, two consecutively described processes may be performed substantially at the same time or may be performed in an order opposite to the described order.

The x axis, the y axis, and the z axis are not limited to three axes of the rectangular coordinate system and may be interpreted in a broader sense. For example, the x axis, the y axis, and the z axis may be perpendicular to one another or may represent different directions that are not perpendicular to one another.

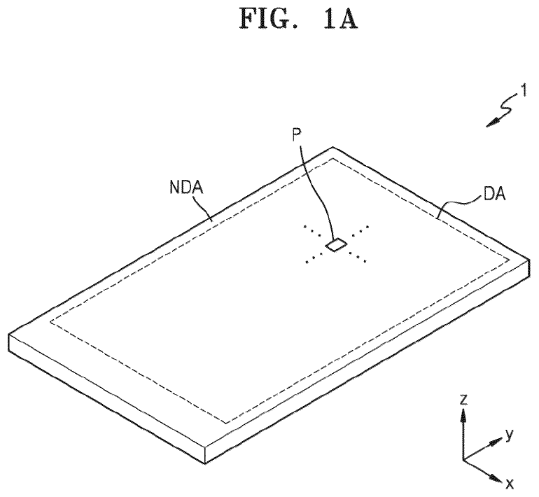

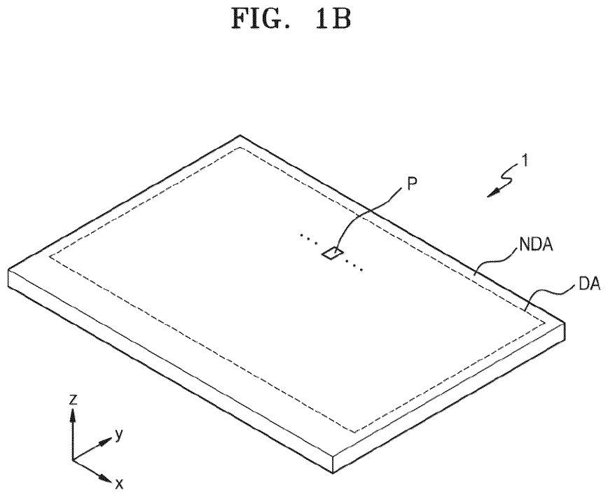

FIGS. 1A and 1B are perspective views schematically illustrating a display apparatus according to some embodiments of the present disclosure.

Referring to FIGS. 1A and 1B, a display apparatus 1 may have a display area DA and a non-display area NDA located outside the display area DA. The display area DA may display an image through subpixels P arranged in the display area DA. The non-display area NDA may be a non-display area arranged outside the display area DA and does not display an image and may entirely surround the display area DA. A driver or the like for providing an electrical signal or power to the display area DA may be arranged in the non-display area NDA. A pad, which is an area to which an electronic device, a printed circuit board, or the like may be electrically connected, may be arranged in the non-display area NDA.

As an example, FIG. 1A illustrates that the display area DA has a polygonal shape (e.g., a tetragonal shape) with an x-direction length less than a y-direction length; however, as another example, FIG. 1B illustrates that the display area DA has a polygonal shape (e.g., a tetragonal shape) with a y-direction length less than an x-direction length. FIGS. 1A and 1B illustrate that the display area DA has a substantially rectangular shape; however, the disclosure is not limited thereto. In other embodiments, the display area DA may have various suitable shapes such as N-gonal shapes (where N is a natural number equal to or greater than 3), circular shapes, or elliptical shapes. FIGS. 1A and 1B illustrate that the display area DA has a shape in which a corner portion thereof includes a vertex at which a straight line and another straight line meet each other; however, in other embodiments, the display area DA may have a polygonal shape with a rounded corner portion.

Hereinafter, for convenience of description, a case where the display apparatus 1 is an electronic apparatus such as a smart phone will be described below; however, the display apparatus 1 of the disclosure is not limited thereto. The display apparatus 1 may be applied to various products such as televisions, notebook computers, monitors, billboards, and Internet of Things (IoT) as well as portable electronic apparatuses such as mobile phones, smart phones, tablet personal computers (PCs), mobile communication terminals, electronic notebooks, electronic books, portable multimedia players (PMPs), navigation devices, and Ultra Mobile PCs (UMPCs). Also, the display apparatus 1 according to some embodiments may be applied to wearable devices such as smart watches, watch phones, glasses-type displays, and head-mounted displays (HMDs). Also, the display apparatus 1 according to some embodiments may be applied to a center information display (CID) arranged at a vehicle's instrument panel or a vehicle's center fascia or dashboard, a room mirror display replacing a vehicle's side mirror, or a display screen arranged at a rear side of a vehicle's front seat as an entertainment device for a vehicle's rear seat.

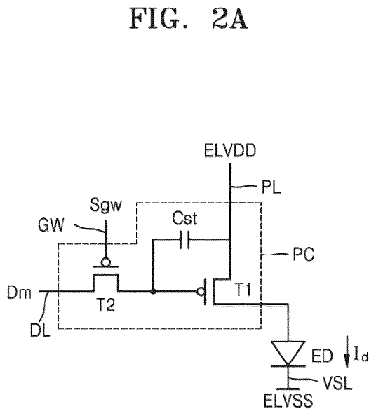

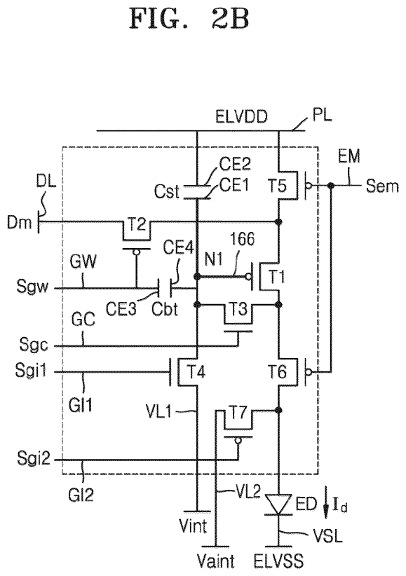

FIGS. 2A and 2B are equivalent circuit diagrams schematically illustrating a light emitting diode corresponding to a subpixel of a display apparatus and a subpixel circuit electrically connected to the light emitting diode, according to some embodiments of the present disclosure.

Referring to FIG. 2A, a light emitting diode ED may be electrically connected to a subpixel circuit PC, and the subpixel circuit PC may include a first transistor T1, a second transistor T2, and a storage capacitor Cst. A subpixel electrode (e.g., an anode) of the light emitting diode ED may be electrically connected to the first transistor T1, and an opposite electrode thereof (e.g., a cathode) may be electrically connected to an auxiliary line VSL and may receive a voltage corresponding to a common voltage ELVSS through the auxiliary line VSL.

The second transistor T2 may be configured to transmit a data signal Dm input through a data line DL, to the first transistor T1 according to a scan signal Sgw input through a scan line GW.

The storage capacitor Cst may be connected to the second transistor T2 and a driving voltage line PL and may store a voltage corresponding to the difference between a voltage received from the second transistor T2 and a driving voltage ELVDD supplied to the driving voltage line PL.

The first transistor T1 may be connected to the driving voltage line PL and the storage capacitor Cst and may control a driving current Id flowing from the driving voltage line PL through the light emitting diode ED in response to a voltage value stored in the storage capacitor Cst. The light emitting diode ED may emit light with a certain brightness according to the driving current Id.

FIG. 2A illustrates a case where the subpixel circuit PC includes two transistors and one storage capacitor; however, embodiments of the disclosure are not limited thereto.

FIG. 2B is an equivalent circuit diagram schematically illustrating a light emitting diode corresponding to a subpixel of a display apparatus and a subpixel circuit electrically connected to the light emitting diode, according to some other embodiments of the present disclosure.

Referring to FIG. 2B, a subpixel circuit PC may include seven transistors and two capacitors, as an example.

The subpixel circuit PC may include first to seventh transistors T1, T2, T3, T4, T5, T6, and T7, a storage capacitor Cst, and a boost capacitor Cbt. In other embodiments, the subpixel circuit PC may not include the boost capacitor Cbt. A subpixel electrode (e.g., an anode) of a light emitting diode ED may be electrically connected to the first transistor T1 via the sixth transistor T6, and an opposite electrode thereof (e.g., a cathode) may be electrically connected to an auxiliary line VSL and may receive a voltage corresponding to a common voltage ELVSS through the auxiliary line VSL.

Some of the first to seventh transistors T1, T2, T3, T4, T5, T6, and T7 may be n-channel MOSFETs (NMOSs), and the others may be p-channel MOSFETs (PMOSs). In some embodiments, as illustrated in FIG. 2B, the third and fourth transistors T3 and T4 may be NMOSs, and the others may be PMOSs. For example, the third and fourth transistors T3 and T4 may be NMOSs including an oxide-based semiconductor material, and the others may be PMOSs including a silicon-based semiconductor material. In other embodiments, the third, fourth, and seventh transistors T3, T4, and T7 may be NMOSs, and the others may be PMOSs.

The first to seventh transistors T1, T2, T3, T4, T5, T6, and T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and a data line DL. The subpixel circuit PC may be electrically connected to voltage lines including, for example, a driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a first electrode (e.g., an anode) of the light emitting diode ED via the sixth transistor T6. One of the first electrode and the second electrode of the first transistor T1 may be a source electrode and the other may be a drain electrode. The first transistor T1 may supply a driving current Id to the light emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be electrically connected to the first electrode of the first transistor T1. The second electrode of the second transistor T2 may be electrically connected to the driving voltage line PL via the fifth transistor T5 when the fifth transistor T5 is turned on. One of the first electrode and the second electrode of the second transistor T2 may be a source electrode and the other may be a drain electrode. The second transistor T2 may perform a switching operation of transmitting a data signal Dm received through the data line DL to the first electrode of the first transistor T1. It does so by being turned on according to the scan signal Sgw, which is received through the scan line GW.

The third transistor T3 may be a compensation transistor for compensating for a threshold voltage of the first transistor T1. A third gate electrode of the third transistor T3 may be connected to the compensation gate line GC. A first electrode of the third transistor T3 may be connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 may be electrically connected to the second electrode of the first transistor T1. The second electrode of the third transistor T3 may be electrically connected to the first electrode (e.g., the anode) of the light emitting diode ED via the sixth transistor T6 when the sixth transistor T6 is turned on. One of the first electrode and the second electrode of the third transistor T3 may be a source electrode and the other may be a drain electrode.

The third transistor T3 may be turned on according to a compensation signal Sgc received through the compensation gate line GC, to electrically connect the first gate electrode and the second electrode (e.g., the drain electrode) of the first transistor T1 to each other to diode-connect the first transistor T1.

The fourth transistor T4 may be a first initialization transistor for initializing the first gate electrode of the first transistor T1 with a particular voltage value. A fourth gate electrode of the fourth transistor T4 may be connected to the first initialization gate line GI1. A first electrode of the fourth transistor T4 may be connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode and the other may be a drain electrode. The fourth transistor T4 may perform an initialization operation of initializing the voltage of the first gate electrode of the first transistor T1 by transmitting a first initialization voltage Vint to the first gate electrode of the first transistor T1 by being turned on according to a first initialization signal Sgi1 received through the first initialization gate line GI1.

The fifth transistor T5 may be an operation control transistor. A fifth gate electrode of the fifth transistor T5 may be connected to the emission control line EM, a first electrode of the fifth transistor T5 may be connected to the driving voltage line PL, and a second electrode of the fifth transistor T5 may be connected to the first electrode of the first transistor T1 and the second electrode of the second transistor T2. One of the first electrode and the second electrode of the fifth transistor T5 may be a source electrode and the other may be a drain electrode.

The sixth transistor T6 may be an emission control transistor. A sixth gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the first electrode (e.g., the anode) of the light emitting diode ED. One of the first electrode and the second electrode of the sixth transistor T6 may be a source electrode and the other may be a drain electrode.

The fifth transistor T5 and the sixth transistor T6 may be simultaneously (e.g., concurrently) turned on according to an emission control signal Sem received through the emission control line EM, to transmit a driving voltage ELVDD to the light emitting diode ED to allow the driving current Id to flow through the light emitting diode ED.

The seventh transistor T7 may be a second initialization transistor for initializing the first electrode (e.g., the anode) of the light emitting diode ED with a particular voltage value. A seventh gate electrode of the seventh transistor T7 may be connected to the second initialization gate line GI2. A first electrode of the seventh transistor T7 may be connected to the second initialization voltage line VL2. The second electrode of the seventh transistor T7 may be connected to the second electrode of the sixth transistor T6 and the first electrode (e.g., the anode) of the light emitting diode ED. The seventh transistor T7 may be turned on according to a second initialization signal Sgi2 received through the second initialization gate line GI2, to transmit a second initialization voltage Vaint to the first electrode (e.g., the anode) of the light emitting diode ED to initialize the first electrode of the light emitting diode ED.

In some embodiments, the second initialization voltage line VL2 may be a subsequent scan line. For example, the second initialization gate line GI2 connected to the seventh transistor T7 of the subpixel circuit PC arranged in an i-th row (where “i” is a natural number) may correspond to a scan line of the subpixel circuit PC arranged in an (i+1)th row. In other embodiments, the second initialization voltage line VL2 may be an emission control line EM. For example, the emission control line EM may be electrically connected to the fifth to seventh transistors T5, T6, and T7.

The storage capacitor Cst may include a lower electrode CE1 and an upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may store the charge corresponding to the difference between the driving voltage ELVDD and the voltage of the first gate electrode of the first transistor T1.

The boost capacitor Cbt may include a third electrode CE3 and a fourth electrode CE4. The third electrode CE3 may be connected to the scan line GW and the second gate electrode of the second transistor T2, and the fourth electrode CE4 may be connected to the node connection line 166 and the first electrode of the third transistor T3. The boost capacitor Cbt may increase the voltage of a first node N1 when the scan signal Sgw supplied through the scan line GW is turned off, which allows the black gradation to be more clearly expressed when the voltage of the first node N1 increases.

The first node N1 may be an area where the first gate electrode of the first transistor T1, the first electrode of the third transistor T3, the second electrode of the fourth transistor T4, and the fourth electrode CE4 of the boost capacitor Cbt are connected.

As an example, FIG. 2B illustrates that the third and fourth transistors T3 and T4 are NMOSs and the first, second, and fifth to seventh transistors T1, T2, T5, T6, and T7 are PMOSs. The first transistor T1, which directly affects the brightness of the display apparatus displaying an image, may be configured to include a semiconductor layer including polycrystalline silicon having high reliability, and accordingly, a high-resolution display apparatus may be implemented.

FIG. 2B illustrates that some transistors are NMOSs and the others are PMOSs; however, the disclosure is not limited thereto. In various other embodiments, the subpixel circuit PC may include three transistors and all of the three transistors may be NMOSs.

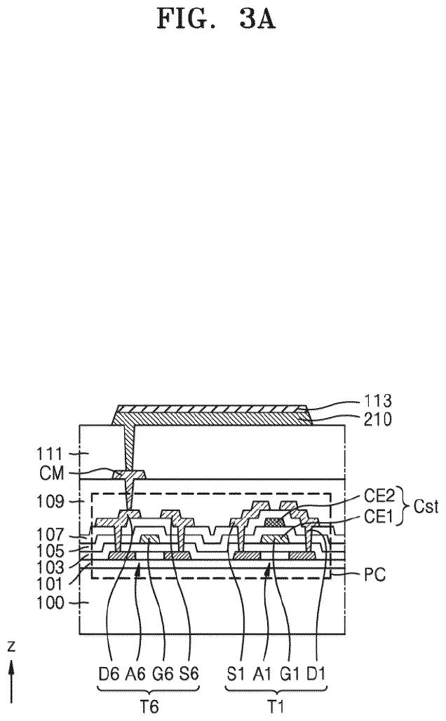

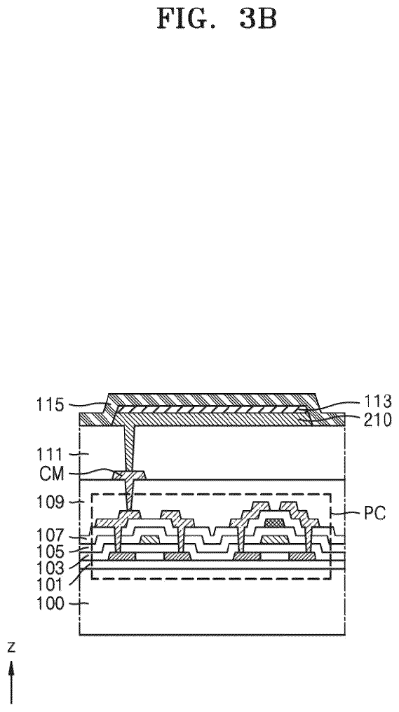

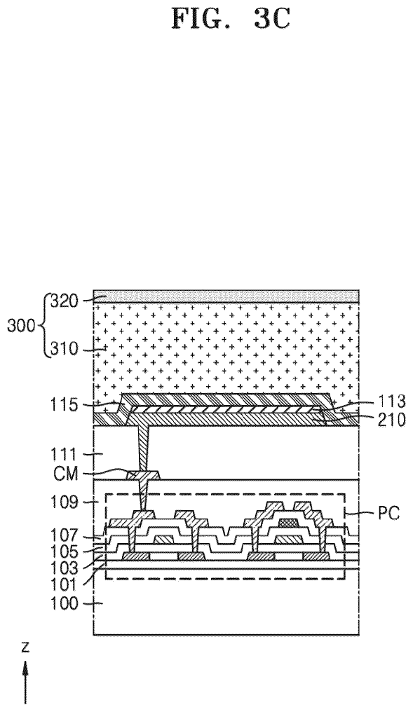

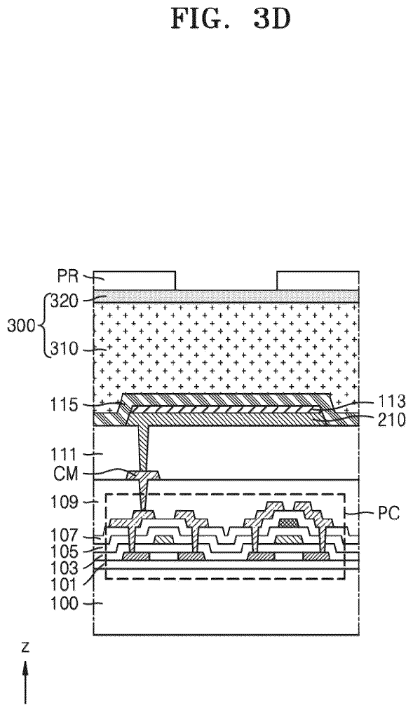

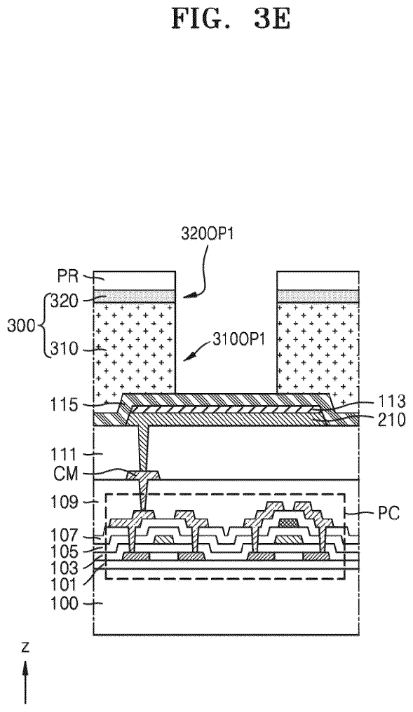

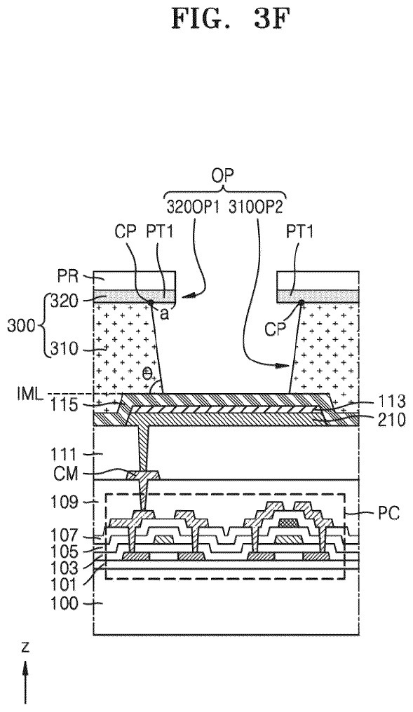

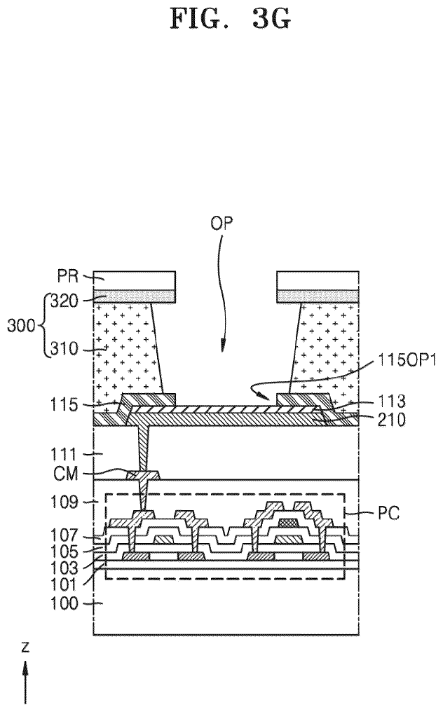

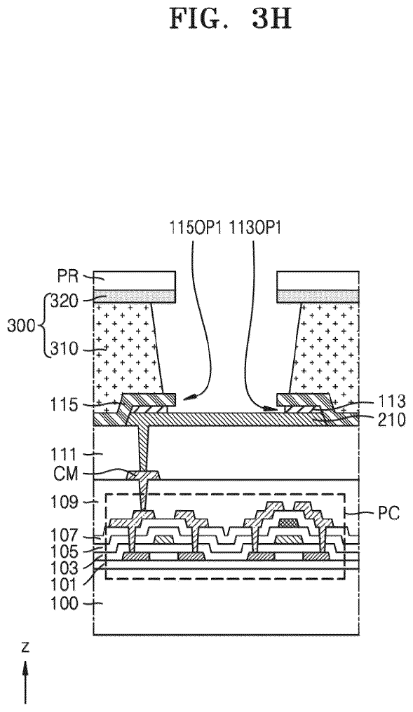

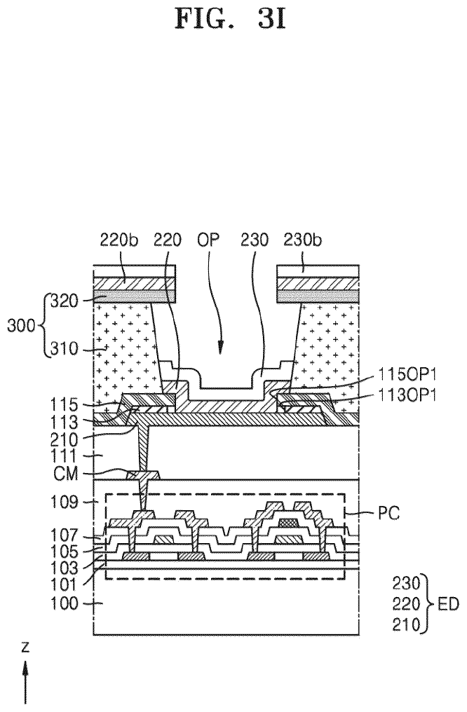

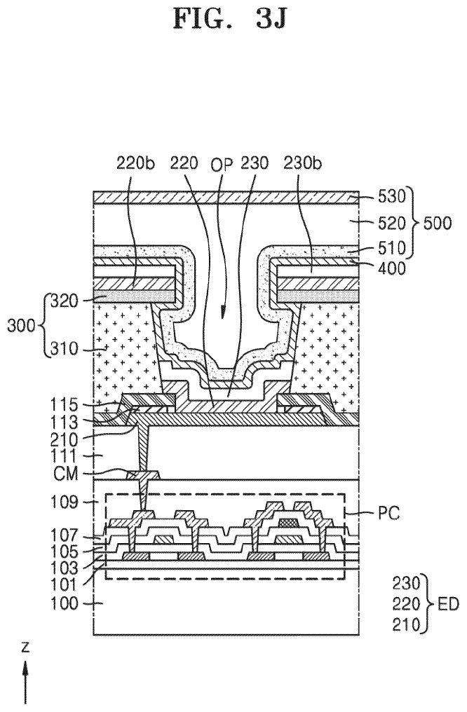

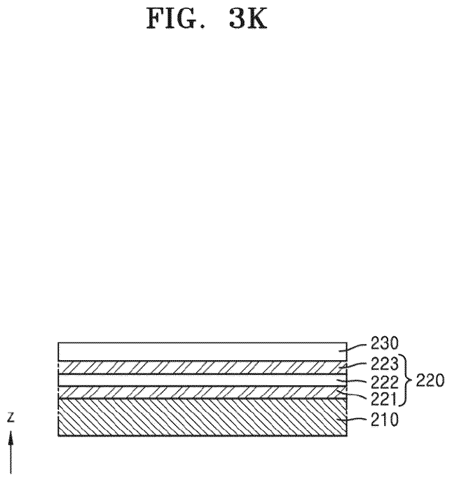

FIGS. 3A to 3J are cross-sectional views schematically illustrating states in a manufacturing process of a display apparatus according to some embodiments of the present disclosure, and FIG. 3K is a cross-sectional view illustrating a stacked structure of a light emitting diode according to some embodiments of the present disclosure.

Referring to FIG. 3A, a subpixel circuit PC may be formed over the substrate 100. The substrate 100 may include a glass material, a polymer resin, or the like. The substrate 100 may include a stacked structure of an inorganic barrier layer and a base layer including a polymer resin. The polymer resin may include polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose triacetate (TAC), cellulose acetate propionate (CAP), and/or the like.

A buffer layer 101 may be arranged on the upper surface of the substrate 100. The buffer layer 101 may prevent or substantially impede impurities from penetrating into the semiconductor layer of the transistor. The buffer layer 101 may include an inorganic insulating material such as silicon nitride, silicon oxynitride, and silicon oxide and may include a single layer or multiple layers including the inorganic insulating material.

The subpixel circuit PC may be disposed over the buffer layer 101. The subpixel circuit PC may include a plurality of transistors and a storage capacitor as described above with reference to FIG. 2A or 2B. As an example, FIG. 3A illustrates a first transistor T1, a sixth transistor T6, and a storage capacitor Cst of the subpixel circuit PC.

The first transistor T1 may include a first semiconductor layer A1 over the buffer layer 101 and a first gate electrode G1 overlapping a channel area of the first semiconductor layer A1. The first semiconductor layer A1 may include a silicon-based semiconductor material, for example, polysilicon. The first semiconductor layer A1 may include a channel area and a first area and a second area arranged on opposite sides (e.g., both sides) of the channel area. The first area and the second area may be areas including a higher concentration of impurities than the channel area, and one of the first area and the second area may correspond to a source area and the other may correspond to a drain area.

The sixth transistor T6 may include a sixth semiconductor layer A6 over the buffer layer 101 and a sixth gate electrode G6 overlapping a channel area of the sixth semiconductor layer A6. The sixth semiconductor layer A6 may include a silicon-based semiconductor material, for example, polysilicon. The sixth semiconductor layer A6 may include a channel area and a first area and a second area arranged on opposite sides (e.g., both sides) of the channel area. The first area and the second area may be areas including a higher concentration of impurities than the channel area, and one of the first area and the second area may correspond to a source area and the other may correspond to a drain area.

The first gate electrode G1 and the sixth gate electrode G6 may include a conductive material including molybdenum (Mo), aluminum (Al), copper (Cu), titanium (Ti), and/or the like, and may include a single-layer or multiple-layer structure including the conductive material. A first gate insulating layer 103 for electrical insulation from the first semiconductor layer A1 and the sixth semiconductor layer A6 may be disposed under the first gate electrode G1 and the sixth gate electrode G6. The first gate insulating layer 103 may include an inorganic insulating material such as silicon nitride, silicon oxynitride, and silicon oxide, and may include a single layer or multiple layers including the inorganic insulating material.

The storage capacitor Cst may include a lower electrode CE1 and an upper electrode CE2 overlapping each other in a plan view. In some embodiments, the lower electrode CE1 of the storage capacitor Cst may include or commonly serve as the first gate electrode G1. For example, the first gate electrode G1 may include the lower electrode CE1 of the storage capacitor Cst. In other words, the first gate electrode G1 and the lower electrode CE1 of the storage capacitor Cst may be integrated with each other.

A first interlayer insulating layer 105 may be arranged between the lower electrode CE1 and the upper electrode CE2 of the storage capacitor Cst. The first interlayer insulating layer 105 may include an inorganic insulating material such as silicon oxide, silicon nitride, or silicon oxynitride, and may include a single-layer or multiple-layer structure including the inorganic insulating material.

The upper electrode CE2 of the storage capacitor Cst may include a low-resistance conductive material such as molybdenum (Mo), aluminum (Al), copper (Cu), and/or titanium (Ti) and may include a single-layer or multiple-layer structure including the low-resistance conductive material.

A second interlayer insulating layer 107 may be disposed over the storage capacitor Cst. The second interlayer insulating layer 107 may include an inorganic insulating material such as silicon oxide, silicon nitride, or silicon oxynitride and may include a single-layer or multiple-layer structure including the inorganic insulating material.

A source electrode S1 and/or a drain electrode D1 electrically connected to the first semiconductor layer A1 of the first transistor T1 may be disposed over the second interlayer insulating layer 107. A source electrode S6 and/or a drain electrode D6 electrically connected to the sixth semiconductor layer A6 of the sixth transistor T6 may be disposed over the second interlayer insulating layer 107. The source electrodes S1 and S6 and/or the drain electrodes D1 and D6 may include aluminum (Al), copper (Cu), and/or titanium (Ti) and may include a single layer or multiple layers including the above material.

A first organic insulating layer 109 may be disposed over the subpixel circuit PC. The first organic insulating layer 109 may include an organic insulating material such as acryl, benzocyclobutene (BCB), polyimide, or hexamethyldisiloxane (HMDSO).

A connection metal CM may be disposed over the first organic insulating layer 109. The connection metal CM may include aluminum (Al), copper (Cu), titanium (Ti) and/or the like, and may include a single layer or multiple layers including the above material.

A second organic insulating layer 111 may be arranged between the connection metal CM and a subpixel electrode 210. The second organic insulating layer 111 may include an organic insulating material such as acryl, benzocyclobutene (BCB), polyimide, or hexamethyldisiloxane (HMDSO). According to the embodiments described with reference to FIG. 3A, the subpixel circuit PC and the subpixel electrode 210 are electrically connected through the connection metal CM; however, in some embodiments, the connection metal CM may be omitted and one organic insulating layer may be located between the subpixel circuit PC and the subpixel electrode 210. In some other embodiments, three or more organic insulating layers may be located between the subpixel circuit PC and the subpixel electrode 210, and the subpixel circuit PC and the subpixel electrode 210 may be electrically connected through a plurality of connection metals.

The subpixel electrode 210 may be formed over the second organic insulating layer 111. The subpixel electrode 210 may be formed as a (semi)transparent electrode or as a reflective electrode. When the subpixel electrode 210 is formed as a (semi)transparent electrode, it may be formed of indium tin oxide (ITO), indium zinc oxide (IZO), zinc oxide (ZnO), indium oxide (In₂O₃), indium gallium oxide (IGO), aluminum zinc oxide (AZO), and/or the like. When the subpixel electrode 210 is formed as a reflective electrode, a reflective layer may be formed of Ag, Mg, Al, Pt, Pd, Au, Ni, Nd, Ir, Cr, or any compound thereof and a layer formed of ITO, IZO, ZnO, In₂O₃, and/or the like may be formed over the reflective layer. In some embodiments, the subpixel electrode 210 has a structure in which an ITO layer, an Ag layer, and an ITO layer are sequentially stacked. The subpixel electrode 210 may be electrically connected to the connection metal CM through a contact hole of the second organic insulating layer 111.

A protection layer 113 may be formed over the subpixel electrode 210. The protection layer 113 may be formed simultaneously (e.g., concurrently) with the subpixel electrode 210. For example, the subpixel electrode 210 and the protection layer 113 may be formed by using the same mask and process. The protection layer 113 may prevent the subpixel electrode 210 from being damaged or substantially reduce damage thereto by gas or liquid materials used in various etching processes or ashing processes included in the manufacturing process of the display apparatus. The protection layer 113 may include a conductive oxide such as indium tin oxide (ITO), indium zinc oxide (IZO), indium gallium zinc oxide (IGZO), indium tin zinc oxide (ITZO), zinc oxide (ZnO), aluminum-doped zinc oxide (AZO), gallium-doped zinc oxide (GZO), zinc tin oxide (ZTO), gallium tin oxide (GTO), and fluorine-doped tin oxide (FTO).

Referring to FIG. 3B, an insulating layer 115 may be formed over the same structure as in FIG. 3A. The insulating layer 115 may be entirely formed over the substrate 100. For example, the insulating layer 115 may overlap the subpixel electrode 210 and the protection layer 113 and may contact the upper surface of the second organic insulating layer 111 on which the subpixel electrode 210 and the protection layer 113 do not exist. The insulating layer 115 may cover the side surface of each of the subpixel electrode 210 and the protection layer 113. The insulating layer 115 may include an inorganic insulating material. Compared to the example in which the insulating layer 115 includes an organic insulating material, when the insulating layer 115 includes an inorganic insulating material, the degradation of the quality of the light emitting diode due to gas emitted from an insulating layer as an organic insulating material during the manufacturing process of the display apparatus may be prevented or substantially reduced (e.g., minimized).

The insulating layer 115 may include an inorganic insulating material such as silicon oxide, silicon nitride, or silicon oxynitride and may include a single-layer or multiple-layer structure including the inorganic insulating material. In some embodiments, the insulating layer 115 may include a two-layer structure of a silicon oxide layer and a silicon nitride layer. The thickness of the silicon oxide layer may be less than the thickness of the silicon nitride layer. In some embodiments, the thickness of the insulating layer 115 may be less than the thickness of the protection layer 113. For example, the thickness of the insulating layer 115 may be about 1000 Å and the thickness of the protection layer 113 may be about 500 Å; however, the disclosure is not limited thereto, and the insulating layer 115 and the protection layer 113 may have any suitable thickness.

Referring to FIG. 3C, a metal bank layer 300 may be formed over the insulating layer 115 illustrated in FIG. 3B. The metal bank layer 300 may include a first metal layer 310 and a second metal layer 320 on the first metal layer 310.

The first metal layer 310 and the second metal layer 320 may include different metals. For example, the first metal layer 310 and the second metal layer 320 may include metals with different etch selectivities. In some embodiments, the first metal layer 310 may be a layer including aluminum (Al), and the second metal layer 320 may be a layer including titanium (Ti).

The thickness of the first metal layer 310 may be greater than the thickness of the second metal layer 320. In some embodiments, the thickness of the first metal layer 310 may be greater than about 5 times the thickness of the second metal layer 320. In other embodiments, the thickness of the first metal layer 310 may be greater than about 6 times, greater than about 7 times, or greater than about 8 times the thickness of the second metal layer 320. In some embodiments, the thickness of the first metal layer 310 may be about 4000 Å to about 8000 Å, and the thickness of the second metal layer 320 may be about 500 Å to about 800 Å. The thickness of the first metal layer 310 may be about 4 times or more, about 5 times or more, or about 6 times or more the thickness of the insulating layer 115.

Referring to FIG. 3D, a photoresist PR may be formed over the metal bank layer 300. The photoresist PR may have an opening overlapping the subpixel electrode 210 and the protection layer 113 in a plan view. A portion of the upper surface of the metal bank layer 300 may be exposed through the opening of the photoresist PR.

Referring to FIG. 3E, a portion of the metal bank layer 300, for example, a portion of the second metal layer 320 and a portion of the first metal layer 310, may be removed by using the photoresist PR as a mask. For example, a portion of the second metal layer 320 and a portion of the first metal layer 310 may be sequentially removed through the opening of the photoresist PR. A portion of the second metal layer 320 and a portion of the first metal layer 310 may be removed by dry etching. During the etching process, the insulating layer 115 and the protection layer 113 may protect the subpixel electrode 210 thereunder.

Through the etching process, an opening 320OP1 overlapping the subpixel electrode 210 and the protection layer 113 and passing from the top surface through the bottom surface of the second metal layer 320 may be formed in the second metal layer 320. An opening 310OP1 overlapping the subpixel electrode 210 and the protection layer 113 and extending from the top surface of the first metal layer 310 to the bottom surface of the first metal layer 310 may be formed in the first metal layer 310.

Referring to FIG. 3F, an undercut opening OP may be formed in the metal bank layer 300 by using the photoresist PR as a mask.

For example, by using the photoresist PR as a mask, a portion of the first metal layer 310 may be further etched and an opening (e.g., a tapered opening) 310OP2 having a greater width than the opening 310OP1 of the first metal layer 310 formed in the above process of FIG. 3E may be formed in the first metal layer 310. In some embodiments, the opening 310OP2 of the first metal layer 310 may have a shape in which the width thereof decreases downward toward the insulating layer 115. For example, the width of the upper portion of the opening 310OP2 of the first metal layer 310 may be greater than the width of the lower portion thereof. In other words, the side surface of the first metal layer 310 facing the opening 310OP2 may include a forward-tapered inclined surface.

In some embodiments, the undercut opening OP may be formed in the metal bank layer 300 by wet etching. For example, the opening 310OP2 of the first metal layer 310 may be formed by wet etching. Because the first metal layer 310 and the second metal layer 320 include metals with different etch selectivities, a portion of the first metal layer 310 may be removed and an opening 310OP2 of the first metal layer 310 having a greater width than the opening 320OP1 of the second metal layer 320 may be formed in the wet etching process. During the etching process for forming the opening 310OP2 of the first metal layer 310, the insulating layer 115, and the protection layer 113 may protect the subpixel electrode 210 thereunder.

Because the opening 310OP2 of the first metal layer 310 has a great diameter while overlapping the opening 320OP1 of the second metal layer 320, the second metal layer 320 may have a first tip PT1 that overhangs over the opening 310OP2.

A portion of the second metal layer 320 defining the opening 320OP1 of the second metal layer 320 may protrude toward the opening 320OP1 from a point CP where the side surface of the first metal layer 310 facing the opening 310OP2 of the first metal layer 310 and the bottom surface of the second metal layer 320 meet each other and may form an undercut structure. A portion of the second metal layer 320 further protruding toward the opening 320OP1 may correspond to the first tip PT1. The length of the first tip PT1, for example, a length “a” from the point CP to the edge (or the side surface) of the first tip PT1, may be about 2 μm or less. In some embodiments, the length “a” of the first tip PT1 of the second metal layer 320 may be about 0.3 μm to about 1 μm or about 0.3 μm to about 0.7 μm.

The inclination angle of the forward-tapered side surface of the first metal layer 310 facing the opening 310OP2 of the first metal layer 310 (e.g., an inclination angle θ of the side surface of the first metal layer 310 with respect to an imaginary line IML parallel to the upper surface of the substrate 100, i.e., the interior angle θ) may be an acute angle equal to or greater than about 60° and less than about 90°.

Referring to FIG. 3G, a portion of the insulating layer 115 may be removed by using the photoresist PR as a mask. A portion of the insulating layer 115 may be removed by dry etching. The width of an opening 115OP1 of the insulating layer 115 may be equal to or substantially equal to the width of an opening area of the photoresist PR and/or the upper width of the opening OP of the metal bank layer 300 (e.g., the width of the opening 320OP1 of the second metal layer 320).

For example, the width of the opening 115OP1 of the insulating layer 115 may be less than the width of the lower portion of the first metal layer 310. The lower portion of the side surface of the first metal layer 310 (e.g., a point where the side surface and the bottom surface of the first metal layer 310 meet each other) may meet the upper surface of the insulating layer 115.

Referring to FIG. 3H, a portion of the protection layer 113 may be removed by using the photoresist PR as a mask. A portion of the protection layer 113 may be removed by wet etching, and the subpixel electrode 210 may be exposed through an opening 113OP1 of the protection layer 113. The width of the opening 113OP1 of the protection layer 113 formed by partially removing the protection layer 113 may be greater than the width of the opening 115OP1 of the insulating layer 115. In other words, the edge (or the side surface) of the protection layer 113 defining the opening 113OP1 of the protection layer 113 may be located under the insulating layer 115.

Thereafter, the photoresist PR may be removed.

Referring to FIG. 3I, an intermediate layer 220 and an opposite electrode 230 may be formed to overlap the subpixel electrode 210 on the structure of FIG. 3H left after removing the photoresist PR. A stacked structure of the subpixel electrode 210, the intermediate layer 220, and the opposite electrode 230 may correspond to a light emitting diode ED. In some embodiments, the intermediate layer 220 and the opposite electrode 230 may be formed through a deposition method such as a thermal deposition method.

The intermediate layer 220 may include an emission layer 222 as illustrated in FIG. 3K. The intermediate layer 220 may include a common layer arranged between the subpixel electrode 210 and the emission layer 222 and/or between the emission layer 222 and the opposite electrode 230. Hereinafter, the common layer between the subpixel electrode 210 and the emission layer 222 will be referred to as a first common layer 221, and the common layer arranged between the emission layer 222 and the opposite electrode 230 will be referred to as a second common layer 223.

The emission layer 222 may include a high-molecular weight organic material or a low-molecular weight organic material for emitting light of a certain color (e.g., red, green, or blue). In other embodiments, the emission layer 222 may include an inorganic material, quantum dots, or the like.

The first common layer 221 may include a hole transport layer (HTL) and/or a hole injection layer (HIL). The second common layer 223 may include an electron transport layer (ETL) and/or an electron injection layer (EIL). The first common layer 221 and the second common layer 223 may include an organic material.

The intermediate layer 220 may have a single-stack structure including a single emission layer or may have a tandem structure that is a multi-stack structure including a plurality of emission layers. In the example of having a tandem structure, a charge generation layer (CGL) may be arranged between a plurality of stacks.

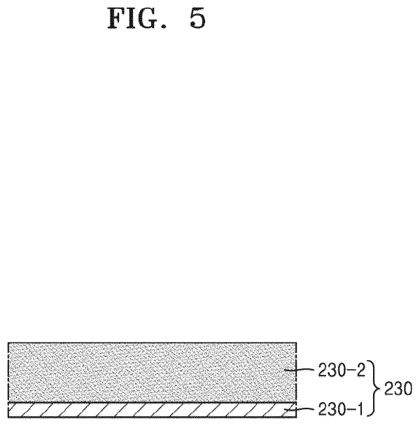

The opposite electrode 230 may include a conductive material having a low work function. In some embodiments, the opposite electrode 230 may include an aluminum (A1)-based alloy. In some examples, the opposite electrode 230 may include an aluminum (A1)-based alloy including aluminum (Al) and at least two elements other than aluminum (Al), which may include at least one of nickel (Ni), palladium (Pd), platinum (Pt), darmstadtium (Ds), and cobalt (Co) and at least one of lanthanum (La), cerium (Ce), praseodymium (Pr), neodymium (Nd), and germanium (Ge). For example, the opposite electrode 230 may include an aluminum-nickel-lanthanum alloy (AlNiLa). The opposite electrode 230 will be described below in further detail with reference to FIG. 5.

Referring back to FIG. 3I, the intermediate layer 220 may overlap and contact the subpixel electrode 210 through the opening OP of the metal bank layer 300, the opening 115OP1 of the insulating layer 115, and the opening 113OP1 of the protection layer 113. The width of an emission area of the light emitting diode ED may be substantially equal to the width of the opening 115OP1 of the insulating layer 115.

Because the intermediate layer 220 and the opposite electrode 230 are deposited without using a separate mask, a deposition material for forming the intermediate layer 220 and a deposition material for forming the opposite electrode 230 may form a dummy intermediate layer 220b and a dummy opposite electrode 230b, respectively, over the metal bank layer 300. The intermediate layer 220 and the dummy intermediate layer 220b may be separated (e.g., spaced apart or offset) from each other, and the opposite electrode 230 and the dummy opposite electrode 230b may be separated (e.g., spaced apart or offset) from each other. The intermediate layer 220 and the dummy intermediate layer 220b may include the same material and/or the same number of sublayers (e.g., may include a first common layer, an emission layer, and a second common layer). The opposite electrode 230 and the dummy opposite electrode 230b may include the same material.

The edge or outer portion (e.g., peripheral portion) of the opposite electrode 230 may extend through the edge or outer portion (e.g., peripheral portion) of the intermediate layer 220 and may contact the side surface of the first metal layer 310. The first metal layer 310 and the opposite electrode 230 may be electrically connected to each other. Herein, “the outer portion (e.g., peripheral portion) of the opposite electrode 230” may refer to “a portion of the opposite electrode 230 including the edge of the opposite electrode 230”.

Referring to FIG. 3J, a capping layer 400 and an encapsulation layer 500 may be formed over the light emitting diode ED.

The capping layer 400 may improve (e.g., increase) the external light emission efficiency of the light emitting diode ED according to the principle of constructive interference. The capping layer 400 may be an organic capping layer including an organic material, an inorganic capping layer including an inorganic material, or a composite capping layer including an organic material and an inorganic material. The capping layer 400 may continuously cover the upper surface of the dummy opposite electrode 230b, the side surface of the metal bank layer 300, and the upper surface of the opposite electrode 230. However, in some embodiments, the capping layer 400 may be omitted.

The encapsulation layer 500 may include at least one inorganic encapsulation layer and at least one organic encapsulation layer. As an example, FIG. 3J illustrates that the encapsulation layer 500 includes a first inorganic encapsulation layer 510, an organic encapsulation layer 520 over the first inorganic encapsulation layer 510, and a second inorganic encapsulation layer 530 over the organic encapsulation layer 520.

The first inorganic encapsulation layer 510 and the second inorganic encapsulation layer 530 may include one or more inorganic materials among aluminum oxide, titanium oxide, tantalum oxide, hafnium oxide, zinc oxide, silicon oxide, silicon nitride, and silicon oxynitride and may be deposited by a method such as chemical vapor deposition. Each of the first inorganic encapsulation layer 510 and the second inorganic encapsulation layer 530 may include a single layer or multiple layers including the above material. The organic encapsulation layer 520 may include a polymer-based material. The polymer-based material may include acryl-based resin, epoxy-based resin, polyimide, polyethylene, and/or the like. In some embodiments, the organic encapsulation layer 520 may include acrylate.

Like the capping layer 400, the first inorganic encapsulation layer 510 with a relatively excellent step coverage may cover at least a portion of the inner surface of the opening OP of the metal bank layer 300 with an undercut structure. In some embodiments, the first inorganic encapsulation layer 510 may be continuously formed to overlap (or cover) the upper surface and side surface of the dummy opposite electrode 230b, the side surface of the dummy intermediate layer 220b, the side surface and bottom surface of the second metal layer 320, the side surface of the first metal layer 310, and the upper surface of the opposite electrode 230, which face the opening OP.

The organic encapsulation layer 520 may be located over the first inorganic encapsulation layer 510 and may fill at least a portion of the opening OP of the metal bank layer 300. The second inorganic encapsulation layer 530 may be disposed over the organic encapsulation layer 520.

In FIGS. 3A to 3J, the metal bank layer 300 is illustrated as including the first metal layer 310 and the second metal layer 320 over the first metal layer 310; however, the disclosure is not limited thereto. In other embodiments, the metal bank layer 300 may include a first metal layer 310, a second metal layer 320 over the first metal layer 310, and a third metal layer under the first metal layer 310, and the third metal layer may include the same material as, or a different material than, the first metal layer.

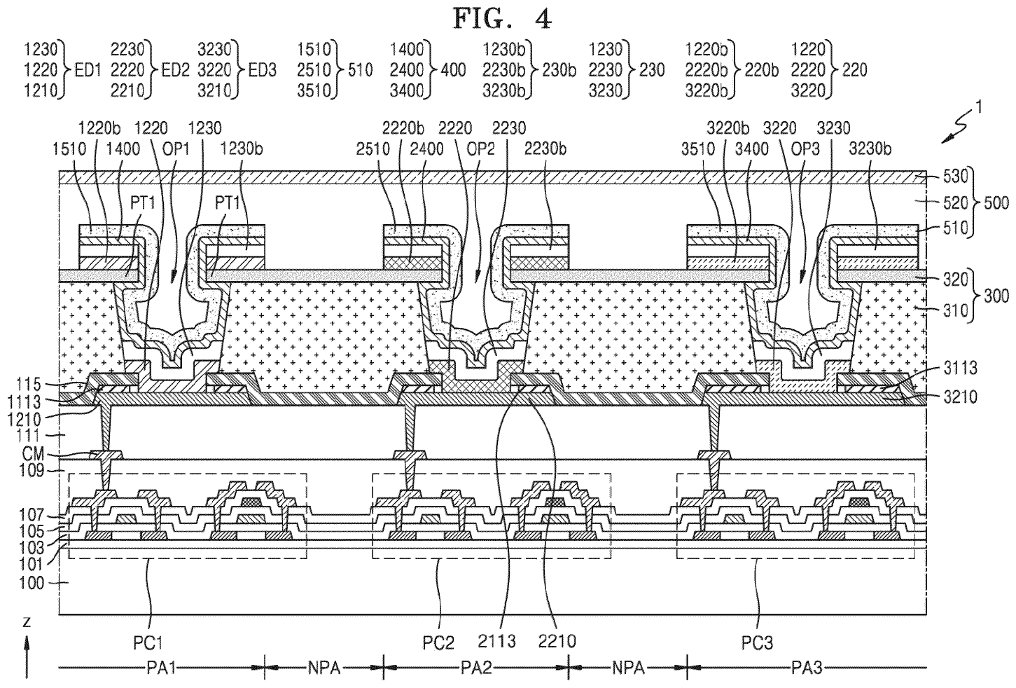

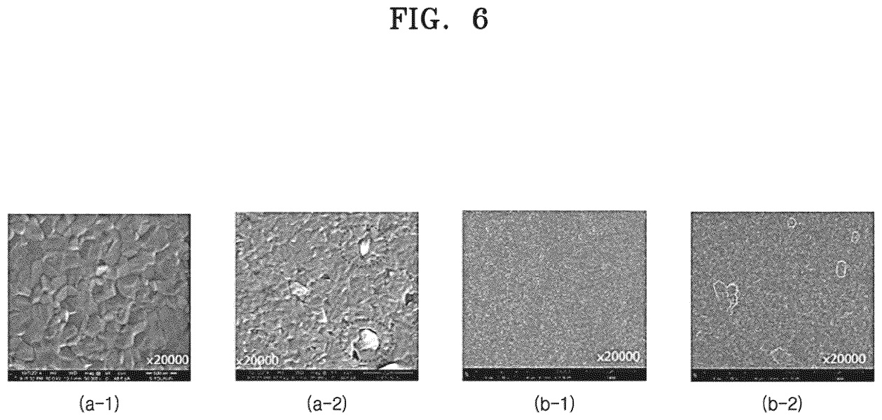

FIG. 4 is a cross-sectional view schematically illustrating a display apparatus according to some embodiments of the present disclosure, and FIG. 5 is a cross-sectional view schematically illustrating an opposite electrode of a display apparatus according to some embodiments of the present disclosure. FIG. 6 is a diagram for describing an opposite electrode of a display apparatus according to some embodiments of the present disclosure.

First, referring to FIG. 4, a display apparatus 1 may include first to third subpixel areas PA1, PA2, and PA3 and a non-subpixel area NPA between adjacent subpixel areas. The planar shape of the display apparatus 1 may be substantially the same as the planar shape of a substrate 100. Thus, when the display apparatus 1 includes the first to third subpixel areas PA1, PA2, and PA3 and the non-subpixel area NPA, the substrate 100 may overlap the first to third subpixel areas PA1, PA2, and PA3 and the non-subpixel area NPA.

Each of first to third light emitting diodes ED1, ED2, and ED3 may be disposed over the substrate 100. The first to third light emitting diodes ED1, ED2, and ED3 may be respectively arranged in the first to third subpixel areas PA1, PA2, and PA3.

First to third subpixel circuits PC1, PC2, and PC3 may be arranged between the substrate 100 and the first to third light emitting diodes ED1, ED2, and ED3. The first to third subpixel circuits PC1, PC2, and PC3 may include transistors and a storage capacitor as described above with reference to FIG. 2A or FIG. 2B. As an example, FIG. 4 illustrates that the first to third subpixel circuits PC1, PC2, and PC3 have the same structure as the subpixel circuit PC described above with reference to FIG. 3A, and a particular structure thereof may be the same or substantially the same as that described above.

The first to third light emitting diodes ED1, ED2, and ED3 respectively electrically connected to the first to third subpixel circuits PC1, PC2, and PC3 may have a stacked structure of a subpixel electrode, an intermediate layer, and an opposite electrode.

For example, the first light emitting diode ED1 may include a first subpixel electrode 1210, a first intermediate layer 1220, and a first opposite electrode 1230. The first subpixel electrode 1210 may be electrically connected to the first subpixel circuit PC1. The second light emitting diode ED2 may include a second subpixel electrode 2210, a second intermediate layer 2220, and a second opposite electrode 2230. The second subpixel electrode 2210 may be electrically connected to the second subpixel circuit PC2. The third light emitting diode ED3 may include a third subpixel electrode 3210, a third intermediate layer 3220, and a third opposite electrode 3230. The third subpixel electrode 3210 may be electrically connected to the third subpixel circuit PC3.

Each of the first intermediate layer 1220, the second intermediate layer 2220, and the third intermediate layer 3220 may include an emission layer and a first common layer and/or a second common layer as described above with reference to FIG. 3K. Here, the emission layer of the first intermediate layer 1220, the emission layer of the second intermediate layer 2220, and the emission layer of the third intermediate layer 3220 may emit light of different colors.

The first opposite electrode 1230, the second opposite electrode 2230, and the third opposite electrode 3230 may be respectively disposed over the first intermediate layer 1220, the second intermediate layer 2220, and the third intermediate layer 3220. The first opposite electrode 1230, the second opposite electrode 2230, and the third opposite electrode 3230 may include the same or substantially the same material.

Each of the first subpixel electrode 1210, the second subpixel electrode 2210, and the third subpixel electrode 3210 may include an inner portion and an outer portion surrounding the inner portion. Herein, “the outer portion (e.g., peripheral portion) of the subpixel electrode” may refer to “a portion of the subpixel electrode including the edge of the subpixel electrode”, and “the inner portion of the subpixel electrode” may refer to “another portion of the subpixel area surrounded by the above outer portion (e.g., peripheral portion)”.

The first intermediate layer 1220 may overlap and contact the inner portion of the first subpixel electrode 1210, and the first opposite electrode 1230 may overlap the first intermediate layer 1220. An insulating layer 115 may be disposed over the outer portion of the first subpixel electrode 1210. The insulating layer 115 may overlap the outer portion of the first subpixel electrode 1210 and may extend onto a second organic insulating layer 111 to cover the side surface of the first subpixel electrode 1210. A first protection layer 1113 may be arranged between the outer portion of the first subpixel electrode 1210 and the insulating layer 115. Each of the insulating layer 115 and the first protection layer 1113 are located over (e.g., cover/overlap) the outer portion of the first subpixel electrode 1210 and may not be located over (e.g., may not cover/overlap) the inner portion of the first subpixel electrode 1210. In other words, each of the insulating layer 115 and the first protection layer 1113 may have an opening overlapping the inner portion of the first subpixel electrode 1210.

Similarly, the second intermediate layer 2220 may overlap and contact the inner portion of the second subpixel electrode 2210, and the second opposite electrode 2230 may overlap the second intermediate layer 2220. The outer portion of the second subpixel electrode 2210 may overlap the insulating layer 115. The third intermediate layer 3220 may overlap and contact the inner portion of the third subpixel electrode 3210, and the third opposite electrode 3230 may overlap the third intermediate layer 3220. The outer portion of the third subpixel electrode 3210 may overlap the insulating layer 115. The insulating layer 115 may overlap the outer portion of each of the second subpixel electrode 2210 and the third subpixel electrode 3210 and may extend onto the second organic insulating layer 111 to cover the side surface of each of the second subpixel electrode 2210 and the third subpixel electrode 3210. A second protection layer 2113 may be arranged between the outer portion of the second subpixel electrode 2210 and the insulating layer 115, and a third protection layer 3113 may be arranged between the outer portion of the third subpixel electrode 3210 and the insulating layer 115.

A metal bank layer 300 have defined therein first to third openings OP1, OP2, and OP3 respectively overlapping the first to third subpixel electrodes 1210, 2210, and 3210. Each of the first to third openings OP1, OP2, and OP3 of the metal bank layer 300 of FIG. 4 may have the same or substantially the same structure as the opening OP (see, e.g., FIG. 3F) described above with reference to FIG. 3F.

For example, each of the first to third openings OP1, OP2, and OP3 may extend from the top surface through the bottom surface of the metal bank layer 300 and may have an undercut cross-sectional structure. The side surface of a first metal layer 310 facing a corresponding opening among the first to third openings OP1, OP2, and OP3 of the metal bank layer 300 may have a forward-tapered shape and may have an inclination angle (e.g., an interior angle) equal to or greater than about 60° and less than about 90°. A second metal layer 320 of the metal bank layer 300 may include a first tip PT1 extending toward a corresponding one of the first to third openings OP1, OP2, and OP3. The length of the first tip PT1 may be about 2 μm or less. In some embodiments, the length of the first tip PT1 may be about 0.3 μm to about 1 μm or may be about 0.3 μm to about 0.7 μm.

In the display apparatus 1 according to some embodiments, due to the structure of the metal bank layer 300 including the first to third openings OP1, OP2, and OP3 with an undercut structure, the first to third intermediate layers 1220, 2220, and 3220 and the first to third opposite electrodes 1230, 2230, 3230 may be deposited and formed without using a separate mask. Thus, damage to the display apparatus 1 due to the mask may be prevented or substantially reduced.

The first opposite electrode 1230 arranged in the first opening OP1 of the metal bank layer 300, the second opposite electrode 2230 arranged in the second opening OP2 of the metal bank layer 300, and the third opposite electrodes 3230 arranged in the third opening OP3 of the metal bank layer 300 may be spatially separated or spaced apart from each other. The first opposite electrode 1230, the second opposite electrode 2230, and the third opposite electrode 3230 may be electrically connected to each other and may have the same voltage level. For example, each of the first opposite electrode 1230, the second opposite electrode 2230, and the third opposite electrode 3230 have the same voltage level as the voltage (e.g., the common voltage) provided by the auxiliary line VSL (see, e.g., FIG. 2A).

Each of the first to third opposite electrodes 1230, 2230, and 3230 may be electrically connected to the auxiliary line VSL (see, e.g., FIG. 2A) through the metal bank layer 300. For example, the outer portion of the first opposite electrode 1230 may be electrically connected to (and may physically contact) the side surface of the metal bank layer 300 (e.g., the side surface of the first metal layer 310) facing the first opening OP1. Further, the metal bank layer 300 may be electrically connected to the auxiliary line VSL (see, e.g., FIG. 2A) such that the first opposite electrode 1230 and the auxiliary line VSL (see, e.g., FIG. 2A) may be electrically connected to each other. The outer portion of the second opposite electrode 2230 may be electrically connected to (and may physically contact) the side surface of the metal bank layer 300 (e.g., the side surface of the first metal layer 310) facing the second opening OP2, and the metal bank layer 300 may be electrically connected to the auxiliary line VSL (see, e.g., FIG. 2A) such that the first opposite electrode 1230 and the auxiliary line VSL (see, e.g., FIG. 2A) may be electrically connected to each other. The outer portion of the third opposite electrode 3230 may be electrically connected to (and may physically contact) the side surface of the metal bank layer 300 (e.g., the side surface of the first metal layer 310) facing the third opening OP3, and the metal bank layer 300 may be electrically connected to the auxiliary line VSL (see, e.g., FIG. 2A) such that the first opposite electrode 1230 and the auxiliary line VSL (see, e.g., FIG. 2A) may be electrically connected to each other.

Moreover, because a material for forming the intermediate layer and a material for forming the opposite electrode are deposited without using a mask, the material for forming the intermediate layer and the material for forming the opposite electrode may be deposited on the metal bank layer 300 as well as in the corresponding one of the first to third openings OP1, OP2, and OP3. At least one dummy intermediate layer and at least one dummy opposite electrode may be disposed over the metal bank layer 300. At least one dummy intermediate layer 220b may be separated (e.g., spaced apart or offset) from the first to third intermediate layers 1220, 2220, and 3220 respectively located in the first to third openings OP1, OP2, and OP3. At least one dummy opposite electrode 230b may be separated (e.g., spaced apart or offset) from the first to third opposite electrodes 1230, 2230, and 3230 respectively located in the first to third openings OP1, OP2, and OP3.

As illustrated in FIG. 4, the dummy intermediate layer 220b may include a first dummy intermediate layer 1220b arranged in the first subpixel area PA1, a second dummy intermediate layer 2220b arranged in the second subpixel area PA2, and a third dummy intermediate layer 3220b arranged in the third subpixel area PA3. The dummy opposite electrode 230b may include a first dummy opposite electrode 1230b arranged in the first subpixel area PA1, a second dummy opposite electrode 2230b arranged in the second subpixel area PA2, and a third dummy opposite electrode 2230b arranged in the third subpixel area PA3. Because the dummy intermediate layer 220b is etched while leaving an area overlapping each subpixel area, the first dummy intermediate layer 1220b, the second dummy intermediate layer 2220b, and the third dummy intermediate layer 3220b may be arranged apart from each other over the second metal layer 320. Likewise, because the dummy opposite electrode 230b is also etched while leaving an area overlapping each subpixel area, the first dummy opposite electrode 1230b, the second dummy opposite electrode 2230b, and the third dummy opposite electrode 3230b be arranged apart from each other.

Because the dummy intermediate layer 220b is separated from an intermediate layer 220 by the undercut structure of the metal bank layer 300, the dummy intermediate layer 220b may include the same or substantially the same material as the intermediate layer 220 of each subpixel area. That is, the first dummy intermediate layer 1220b may include the same or substantially the same material as the first intermediate layer 1220, the second dummy intermediate layer 2220b may include the same or substantially the same material as the second intermediate layer 2220, and the third dummy intermediate layer 3220b may include the same or substantially the same material as the third intermediate layer 3220. However, because the first intermediate layer 1220, the second intermediate layer 2220, and the third intermediate layer 3220 include different materials to emit light of different colors, the first dummy intermediate layer 1220b, the second dummy intermediate layer 1220b, and the third dummy intermediate layer 3220b may also include different materials.

Because the dummy opposite electrode 230b is also separated from an opposite electrode 230 by the undercut structure of the metal bank layer 300, the dummy opposite electrode 230b may include the same or substantially the same material as the opposite electrode 230 of each subpixel area. That is, the first dummy opposite electrode 1230b may include the same or substantially the same material as the first opposite electrode 1230, the second dummy opposite electrode 2230b may include the same or substantially the same material as the second opposite electrode 2230, and the third dummy opposite electrode 3230b may include the same or substantially the same material as the third opposite electrode 3230. Further, because the first opposite electrode 1230, the second opposite electrode 2230, and the third opposite electrode 3230 may include the same or substantially the same material, the first dummy opposite electrode 1230b, the second dummy opposite electrode 2230b, and the third dummy opposite electrode 3230b may also include the same or substantially the same material. That is, the first opposite electrode 1230, the first dummy opposite electrode 1230b, the second opposite electrode 2230, the second dummy opposite electrode 2230b, the third opposite electrode 3230, the third dummy opposite electrode 3230b may include the same or substantially the same material.

As illustrated in FIG. 5, the opposite electrode 230 may include a double-layer structure. The opposite electrode 230 may include a first layer 230-1 and a second layer 230-2 disposed over the first layer 230-1. That is, each of the first opposite electrode 1230, the second opposite electrode 2230, and the third opposite electrode 3230 may include a first layer 230-1 and a second layer 230-2 including the same or substantially the same material.

First, the first layer 230-1 of the opposite electrode 230 may include a metal having a low work function. Particularly, the first layer 230-1 may include at least one of ytterbium (Yb), scandium (Sc), vanadium (V), yttrium (Y), indium (In), cerium (Ce), samarium (Sm), europium (Eu), and terbium (Tb). In some embodiments, the first layer 230-1 of the opposite electrode 230 may include ytterbium (Yb). The first layer 230-1 may function as an electron injection layer. In such examples, when the first layer 230-1 includes a metal having a low work function like ytterbium (Yb), the electron injection barrier of the light emitting diode ED may be lowered and simultaneously the light emission efficiency may be improved (e.g., increased). The first layer 230-1 may be thin with a thickness of about 5 Å to about 30 Å.

Next, the second layer 230-2 of the opposite electrode 230 may include an aluminum (Al)-based alloy including aluminum (Al) and at least two elements other than aluminum (Al). For example, the second layer 230-2 of the opposite electrode 230 may include an aluminum (Al)-based alloy including aluminum (Al), a first element, and a second element. In such examples, the first element may include at least one of a Group 9 metal element and a Group 10 metal element. The second element may include at least one of a lanthanum Group metal element and germanium (Ge). Particularly, the first element may include at least one of nickel (Ni), palladium (Pd), platinum (Pt), darmstadtium (Ds), and cobalt (Co), and the second element may be at least one of lanthanum (La), cerium (Ce), praseodymium (Pr), neodymium (Nd), and germanium (Ge). The second layer 230-2 of the opposite electrode 230 is not limited to including the first element and the second element, and may further include an element other than aluminum (Al), the first element, and the second element. The further included element may include at least one of nickel (Ni), palladium (Pd), platinum (Pt), darmstadtium (Ds), cobalt (Co), lanthanum (La), cerium (Ce), praseodymium (Pr), neodymium (Nd), and germanium (Ge).

In some embodiments, the aluminum (Al)-based alloy included in the second layer 230-2 may include an aluminum-nickel-lanthanum alloy (AlNiLa). However, the disclosure is not limited thereto, and the aluminum (Al)-based alloy included in the second layer 230-2 may include aluminum-neodymium (AlNd), aluminum-nickel-germanium-lanthanum (AlNiGeLa), aluminum-cobalt-germanium-lanthanum (AlCoGeLa), or the like.

When the second layer 230-2 includes an aluminum (Al) alloy, the surface flatness may be better than when the second layer 230-2 includes only pure aluminum (Al). Referring to FIGS. 6, (a-1) and (a-2) are images of the surface of a material including only aluminum (Al) detected by a scanning probe microscope (e.g., an atomic force microscope (AFM)), and (b-1) and (b-2) may be images of the surface of a material including an aluminum-nickel-lanthanum alloy (AlNiLa) detected by a scanning probe microscope (e.g., an atomic force microscope (AFM)). (a-1) is an image before heat treatment of a sample deposited with only aluminum (Al), and (a-2) is an image after heat treatment of a sample deposited with aluminum (Al). (b-1) is an image before heat treatment of a sample deposited with an aluminum-nickel-lanthanum alloy (AlNiLa), and (b-2) is an image after heat treatment of a sample deposited with an aluminum-nickel-lanthanum alloy (AlNiLa). Compared to the images (b-1) and (b-2), in the images (a-1) and (a-2), surface agglomeration occurs more and the grain boundary of a thin film is clearly formed. Also, in comparing the images (a-2) and (b-2) that are samples after heat treatment, protrusions such as hillocks occur more in the (a-2) image than in the (b-2) image. That is, it may be seen that the surface flatness the material deposited with an aluminum-nickel-lanthanum alloy (AlNiLa) is better than the surface flatness of the material deposited only with aluminum (Al).

Also, when the second layer 230-2 includes an aluminum (Al) alloy, there may be an effect of enabling dry etching at room temperature. Referring to FIG. 4, the first dummy opposite electrode 1230b, the second dummy opposite electrode 2230b, and the third dummy opposite electrode 3230b may be etched while leaving only the portions respectively overlapping the first subpixel area PA1, the second subpixel area PA2, and the third subpixel area PA3. Accordingly, in the structure in which the first to third light emitting diodes ED1, ED2, and ED3 are patterned by using the metal bank layer 300 as illustrated in FIG. 4, a material capable of being easily etched may be applied to the opposite electrode 230 and the dummy opposite electrode 230b. Table 1 below shows the comparison between the example of using a silver-magnesium alloy (AgMg) and the example of using an aluminum (Al)-based alloy as the material of the second layer 230-2, with respect to the dry etching temperature at which dry etching is possible.

TABLE 1

| Opposite | | | Aluminum-based |
|---|---|---|---|
| electrode | Silver-magnesium alloy | | alloy |
| metal | Ag | Mg | Al |
| Dry etching | AgF(g) 620° C. | MgF₂(g) 1000° C. | AlF₃(g) 677.5° C. |
| gas F | | | |
| Dry etching | AgCl(g) 595° C. | MgCl₂(g) 545° C. | Al₂Cl₆(g) 20° C. |
| gas Cl | | | |

Referring to Table 1, the dry etching temperature may be about 545° C. to about 1000° C. in the example of a silver-magnesium alloy (AgMg), and the dry etching temperature may be about 20° C. or about 677.5° C. in the example of an aluminum (Al)-based alloy. Particularly, in the example where the second layer 230-2 of the opposite electrode 230 includes silver (Ag), in the dry etching process, etching may be possible at 620° C. by using fluorine (F) gas and etching may be possible at 595° C. by using chlorine (CI) gas. In the example where the second layer 230-2 of the opposite electrode 230 includes magnesium (Mg), in the dry etching process, etching may be possible at 1,000° C. by using fluorine (F) gas and etching may be possible at 545° C. by using chlorine (CI) gas. On the other hand, in the example in which the second layer 230-2 of the opposite electrode 230 includes aluminum (Al), in the dry etching process, etching may be possible at 677.5° C. by using fluorine (F) gas but etching may be possible at 20° C. by using chlorine (CI) gas. That is, when a silver-magnesium alloy (AgMg) is used as the material of the second layer 230-2, etching may be performed at least 545° C. or more by using any dry etching gas, and when an aluminum (Al)-based alloy is used as the material of the second layer 230-2, etching may be performed even at room temperature by using chlorine (CI) gas. As a result, when the second layer 230-2 of the opposite electrode 230 is formed by using an aluminum (Al)-based alloy, the opposite electrode 230 and the dummy opposite electrode 230b may be easily dry-etched.

Also, when the second layer 230-2 includes an aluminum (Al)-based alloy, the opposite electrode 230 may be formed thick. In some embodiments, the thickness of the second layer 230-2 using an aluminum (Al)-based alloy may be about 100 Å to about 200 Å. The transmittance of the opposite electrode 230 using the second layer 230-2 described above may be about 40% to about 60%. For example, when the second layer 230-2 is formed of an aluminum (Al)-based alloy, the second layer 230-2 may be formed with a thickness of about 1.3 times compared to the example in which the second layer 230-2 is formed of a silver-magnesium alloy (AgMg) that has been frequently used as a material for an existing opposite electrode. Particularly, assuming that the opposite electrode is formed with the same transmittance of about 50%, the second layer 230-2 may be formed with a thickness of 100 Å in the example of using a silver-magnesium alloy (AgMg) and the second layer 230-2 may be formed with a thickness of 130 Å in the example of using an aluminum (Al)-based alloy. This may be because the aluminum (Al)-based alloy may have a higher transmittance than the silver-magnesium alloy (AgMg) at the same thickness. Also, because the aluminum (Al)-based alloy may have a lower electrical conductivity than the silver-magnesium alloy (AgMg), the skin depth thereof may be greater by about 30%. Thus, the thickness of the second layer 230-2 using the aluminum (Al)-based alloy may be about 1.3 times greater than the thickness of the second layer 230-2 using the silver-magnesium alloy (AgMg).

As described above, when the second layer 230-2 is formed thick with the aluminum (Al)-based alloy, the opposite electrode 230 may stably receive the common voltage. As described above, because the metal bank layer 300 is electrically connected to the auxiliary line VSL and the opposite electrode 230 contacts the metal bank layer 300, the opposite electrode 230 may receive the common voltage. In this example, as the thickness of the opposite electrode 230 increases, the area where the outer portion of the opposite electrode 230 contacts the side surface of the metal bank layer 300 may increase. As a result, when the aluminum (Al)-based alloy is used for the second layer 230-2 of the opposite electrode 230, because the second layer 230-2 may be formed thick, the opposite electrode 230 may be stably connected to the metal bank layer 300 to receive the common voltage.

However, the content of at least two elements included in the aluminum (Al)-based alloy may be 0.1 at % or less. Particularly, the content of at least two elements included in the second layer 230-2 may be about 0.05 at % (atomic percentage) to about 0.1 at %. For example, when the aluminum (Al)-based alloy included in the second layer 230-2 is the aluminum-nickel-lanthanum alloy (AlNiLa), the sum of the content of nickel (Ni) and the content of lanthanum (La) may be about 0.05 at % to about 0.1 at %.

When the content of materials other than aluminum (Al) in the aluminum alloy of the second layer 230-2 increases, the surface flatness may increase as described above with reference to FIG. 6, but the resistance of the second layer 230-2 may increase. Accordingly, by forming the content of the first element and the second element included in the aluminum alloy at 0.1 at % or less, an increase in the resistance of the second layer 230-2 may be prevented or substantially mitigated. However, the content of the first element and the second element included in the aluminum alloy may be 0.05 at % or more to maintain the high surface flatness of the second layer 230-2. In other embodiments, even when there are other elements further included in addition to the first element and the second element, the content of materials other than aluminum (Al) may be 0.1 at % or less.

In some embodiments, when an aluminum (Al)-based alloy included in the second layer 230-2 is an aluminum-nickel-lanthanum alloy (AlNiLa), the content of lanthanum (La) may be equal to or greater than the content of nickel (Ni). The content of nickel (Ni) may be about 0.01 at % to about 0.05 at %, and the content of lanthanum (La) may be about 0.01 at % to about 0.1 at %. For example, when the second layer 230-2 includes an aluminum-nickel-lanthanum alloy (AlNiLa), the content of aluminum (Al) may be about 99.94 at %, the content of nickel (Ni) may be about 0.02 at %, and the content of lanthanum (La) may be about 0.04 at %.

In conclusion, when the second layer 230-2 includes an aluminum (Al)-based alloy, the specific resistance thereof may be higher than the specific resistance of pure aluminum (Al); however, an excessive increase in the specific resistance of the aluminum alloy may be prevented or substantially mitigated by adjusting the content of materials other than aluminum (Al) in the aluminum alloy as described above.

Referring back to FIG. 4, a capping layer 400 may be disposed over the opposite electrode 230 and the dummy opposite electrode 230b. The capping layer 400 may improve (e.g., increase) the external light emission efficiency of the first to third light emitting diodes ED1, ED2, and ED3. The capping layer 400 may continuously cover the upper surface of the dummy opposite electrode 230b, the side surface of the metal bank layer 300, and the upper surface of the opposite electrode 230. The capping layer 400 may include a first capping layer 1400 arranged in the first subpixel area PA1, a second capping layer 2400 arranged in the second subpixel area PA2, and a third capping layer 3400 arranged in the third subpixel area PA3. For example, the first capping layer 400 may overlap the upper surface and side surface of the first dummy opposite electrode 1230b, the side surface of the first dummy intermediate layer 1220b, the side surface and bottom surface of the second metal layer 320 corresponding to the first tip PT1, the side surface of the first metal layer 310, and the upper surface of the first opposite electrode 1230. The material of the capping layer 400 may be the same or substantially the same as that described above with reference to FIG. 3J.

The first to third light emitting diodes ED1, ED2, and ED3 may be encapsulated by an encapsulation layer 500. As an example, FIG. 4 illustrates that the encapsulation layer 500 includes a first inorganic encapsulation layer 510, an organic encapsulation layer 520 over the first inorganic encapsulation layer 510, and a second inorganic encapsulation layer 530 over the organic encapsulation layer 520. The materials of the first inorganic encapsulation layer 510, the organic encapsulation layer 520, and the second inorganic encapsulation layer 530 may be the same as those described above with reference to FIG. 3J.

The first inorganic encapsulation layer 510 may cover the structure and/or layer under the first inorganic encapsulation layer 510. For example, the first inorganic encapsulation layer 510 with a relatively excellent step coverage may cover the inner structure and/or layer of each of the first to third openings OP1, OP2, and OP3. The first inorganic encapsulation layer 510 may include a first subpixel inorganic encapsulation layer 1510 arranged in the first subpixel area PA1, a second subpixel inorganic encapsulation layer 2510 arranged in the second subpixel area PA2, and a third subpixel inorganic encapsulation layer 3510 arranged in the third subpixel area PA3. For example, the first subpixel inorganic encapsulation layer 1510 may overlap the upper surface and side surface of the first dummy opposite electrode 1230b, the side surface of the first dummy intermediate layer 1220b, the side surface and bottom surface of the second metal layer 320 corresponding to the first tip PT1, the side surface of the first metal layer 310, and the upper surface of the first opposite electrode 1230. A portion of the organic encapsulation layer 520 may at least partially fill each of the first to third openings OP1, OP2, and OP3.

As described above, according to some embodiments, the display apparatus may implement a high-quality image by including the opposite electrode that may be easily etched and may stably contact the metal bank layer. However, these effects are merely examples and the scope of the disclosure is not limited thereto.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

It will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.”

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims and equivalents thereof.

What is claimed is:

1. A display apparatus comprising:
a first subpixel electrode;
a metal bank layer having a first opening overlapping the first subpixel electrode, and comprising a first metal layer and a second metal layer on the first metal layer;
a first intermediate layer overlapping the first subpixel electrode through the first opening of the metal bank layer; and
a first opposite electrode on the first intermediate layer and positioned in the first opening of the metal bank layer,
wherein the first opposite electrode comprises an aluminum (Al)-based alloy comprising aluminum (Al) and at least two elements other than the aluminum (Al).

2. The display apparatus of claim 1, wherein a sum of contents of the at least two elements is about 0.05 at % to about 0.1 at %.

3. The display apparatus of claim 1, wherein the at least two elements of the first opposite electrode comprise:
at least one of nickel (Ni), palladium (Pd), platinum (Pt), darmstadtium (Ds), and cobalt (Co); and
at least one of lanthanum (La), cerium (Ce), praseodymium (Pr), neodymium (Nd), and germanium (Ge).

4. The display apparatus of claim 1, wherein the at least two elements of the first opposite electrode comprise:
at least one of a Group 9 metal element and a Group 10 metal element; and
at least one of a lanthanum group metal element and germanium (Ge).

5. The display apparatus of claim 3, wherein the first opposite electrode comprises an aluminum (Al)-based alloy comprising aluminum (Al), nickel (Ni), and lanthanum (La),
a content of the nickel (Ni) is about 0.01 at % to about 0.05 at %, and
a content of the lanthanum (La) is about 0.01 at % to about 0.1 at %.

6. The display apparatus of claim 5, wherein the content of the lanthanum (La) is equal to or greater than the content of the nickel (Ni).

7. The display apparatus of claim 1, wherein the first opposite electrode comprises a first layer and a second layer on the first layer, and
wherein the second layer comprises an aluminum (Al)-based alloy.

8. The display apparatus of claim 7, wherein the first layer comprises at least one of ytterbium (Yb), scandium (Sc), vanadium (V), yttrium (Y), indium (In), cerium (Ce), samarium (Sm), europium (Eu), and terbium (Tb).

9. The display apparatus of claim 8, wherein a thickness of the second layer is about 100 Å to about 200 Å.

10. The display apparatus of claim 9, wherein a thickness of the first layer is about 5 Å to about 30 Å.

11. The display apparatus of claim 9, wherein a transmittance of the first opposite electrode comprising the second layer is about 40% to about 60%.

12. The display apparatus of claim 1, wherein an outer portion of the first opposite electrode contacts a side surface of the first metal layer facing the first opening.

13. The display apparatus of claim 1, wherein a portion of the second metal layer facing the first opening of the metal bank layer comprises a tip extending toward the first opening from a point where a bottom surface of the second metal layer and a side surface of the first metal layer contact each other.

14. The display apparatus of claim 1, further comprising:
a first dummy intermediate layer comprising a same material as the first intermediate layer and on the second metal layer; and
a first dummy opposite electrode comprising a same material as the first opposite electrode and on the first dummy intermediate layer.

15. The display apparatus of claim 12, further comprising:
an insulating layer on the first subpixel electrode and under the metal bank layer; and
a protection layer arranged between an outer portion of the first subpixel electrode and the insulating layer,
wherein the protection layer comprises a transparent conductive oxide (TCO).

16. A display apparatus comprising:
a first subpixel electrode;
a metal bank layer having a first opening overlapping the first subpixel electrode, and comprising a first metal layer and a second metal layer over the first metal layer;
a first intermediate layer overlapping the first subpixel electrode in the first opening of the metal bank layer;
a first opposite electrode on the first intermediate layer and positioned in the first opening of the metal bank layer;
a first dummy intermediate layer comprising a same material as the first intermediate layer and on the second metal layer; and
a first dummy opposite electrode comprising a same material as the first opposite electrode and on the first dummy intermediate layer,
wherein the first opposite electrode and the first dummy opposite electrode comprise an aluminum (Al)-based alloy comprising aluminum (Al) and at least two elements other than the aluminum (Al).

17. The display apparatus of claim 16, wherein a sum of contents of the at least two elements is about 0.05 at % to about 0.1 at %.

18. The display apparatus of claim 16, wherein the at least two elements of the first opposite electrode and the first dummy opposite electrode comprise:
at least one of nickel (Ni), palladium (Pd), platinum (Pt), darmstadtium (Ds), and cobalt (Co); and
at least one of lanthanum (La), cerium (Ce), praseodymium (Pr), neodymium (Nd), and germanium (Ge).

19. The display apparatus of claim 16, wherein the first opposite electrode and the first dummy opposite electrode comprise a first layer and a second layer on the first layer,
wherein the first layer comprises at least one of ytterbium (Yb), scandium (Sc), vanadium (V), yttrium (Y), indium (In), cerium (Ce), samarium (Sm), europium (Eu), and terbium (Tb), and
wherein the second layer comprises the aluminum (Al)-based alloy.

20. The display apparatus of claim 16, further comprising:
a second subpixel electrode;
a second intermediate layer overlapping the second subpixel electrode and positioned in a second opening of the metal bank layer;
a second opposite electrode overlapping the second intermediate layer and positioned in the second opening of the metal bank layer;
a second dummy intermediate layer comprising a same material as the second intermediate layer and on the second metal layer; and
a second dummy opposite electrode comprising a same material as the second opposite electrode and on the second dummy intermediate layer,
wherein the first dummy opposite electrode and the second dummy opposite electrode are offset from each other, and
wherein the first opposite electrode, the second opposite electrode, the first dummy opposite electrode, and the second dummy opposite electrode comprise a same material.
